(19) United States
(12) Patent Application Publication
(10) Pub. No.: US 2012/0211046 A1
(43) Pub. Date: Aug. 23, 2012

(54) Electrical Power Generation

(75) Inventors: David Smyth, Queensland (AU); Grant Behrendorff, Queensland (AU)

(73) Assignee: Energy Innovations Pty Ltd., Alice Springs (AU)

(21) Appl. No.: 13/032,394

(22) Filed: Feb. 22, 2011

(51) Int. Cl. H01L 31/042

(52) U.S. Cl. 136/244

(57) ABSTRACT

A solar cell and alternating low voltage electrical transmission system assembly having a curved solar cell panel supported on the side of an electrical transmission pole partially wrapping around the pole, and held in a spaced apart relationship by having upper and lower spacing blocks which are also held to the pole by in each case a strap.

This invention relates to electrical power generation in particular to a solar cell and alternating low voltage electrical transmission system.

### BACKGROUND OF THE INVENTION

The use of solar cell panels is now well established and includes the use of a number of flat panels covering large areas of ground and being individually supported with either fixed axis or one or two axial boards to provide tracking.

Such a solar cell farm however uses significant land areas and are also visually distinctive and to some extent at least to some people visually obnoxious.

We have proposed attaching solar cell panels to electrical transmission poles where there is no additional space of land required, and furthermore, electrical power being generated is generated in a distributed way where much of this generation will be close to the end user and there are electrical efficiencies because power for those end users does not have to be transmitted long distances.

There are however significant problems with such a proposal.

The first of these is the problem that locating flat panels in the air is about as visually obnoxious as any other large flat panel would be in sensitive suburban or like areas.

Secondly, facing a flat panel in an elevated position on its electrical transmission pole introduces a wind loading factor that is not only applicable to the pole supporting the flat panel, but to adjacent poles which are connected by transmission wires.

Accordingly, if one pole subject to larger wind loading and is caused to fail, this will have a significant contribution to failure of other poles whether or not they also have flat panel solar cells attached thereto.

A further problem however is also the difficulty of obtaining efficiency from a flat panel which in order to improve efficiency could be supported so that its planar alignment will be square to the sun's path.

This implicitly then adds to the visual interference of the panel, and unless expensive tracking options are included, it becomes economically very difficult indeed to justify the concept.

A further problem is also that a solar cell panel is by its nature fragile therefore, especially when elevated substantially, needs a significant framing support so that it can firstly be internally held substantially rigidly, and also that its fittings to a pole can be such that these will adequately hold the more substantial framing elements appropriately and effectively even in very windy conditions.

The above aspects are especially aggravated where the application might be in areas of extended weather events such as cyclones or hurricanes.

Ultimately, it is a question of whether economically such additional strengths and modifications can justify the economic advantage of having the distributed solar network.

A further problem exists where an inclined flat panel is supported in that birds may either directly sit and leave droppings on it or have birds sit on wires above the panel and leave there droppings on the panel.

A next problem is that with a flat panel with a modest incline is that it will firstly also collect dust on its upper surface and then with only a modest incline even rain is unlikely to clean its upper surface.

We have developed an arrangement that reduces significantly the problems indicated above.

We have proposed a solar panel where it is curved about an elongate axis and then positioned so that the curve partially wraps around a transmission pole to which it is attached.

Significant advantages arise from this arrangement.

Firstly, because a much larger area can be positioned in this way than using an inclined flat panel, it is more economically efficient. Further, because of the curved shape, it becomes internally much stiffer and therefore will not need anywhere near the same framing as a flat panel.

Further however, the visual impact of such a solar panel is very much less than a flat panel in so far that it will generally merge with the outline of the transmission pole itself and be visually indistinct.

Further, because of its then implicit streamline shape it becomes very much less of a wind sail and therefore, from an engineering point of view, can become viable to use even to an extent where weather conditions may allow for quite aggressive wind conditions such as cyclones or hurricanes.

A problem has arisen however as to how to connect such panels to poles especially in so far that the poles can derive from inconsistent shapes especially where these are wooden poles you also may have inconsistent diameters along their length.

Further having such a curved panel this then is supported to be vertical. This reduces the opportunity for bird droppings to ensnare the solar cell panel face. Also, a vertical surface will implicitly reduce the amount of dust that will collect on the surface and moreover when it does rain it is noticed that the cleaning action of the rain onto a vertical surface will generally have a significant cleaning effect of whatever debris may have been gathered.

We have discovered an arrangement and assembly that provides significant advantage when attaching such solar cell panels to electrical transmission poles which takes advantage of the natural internal rigidity provided by the curved shape, allows for adequate gap between the pole outer surface and the inner side of the panel which thereby allows for cooling convection currents, is economic to install and robust in use over a longer time.

One form of this invention, although this need not necessarily be the only or indeed the broadest form of this, there is proposed a solar cell and alternating low voltage electrical transmission system assembly comprising or including an electricity transmission pole, solar cell panel attached to a side of the pole, the solar cell panel having a plurality of cells commonly electrically connected, an inverter effecting an electrical connection between the plurality of cells and the electrical transmission system, the panel being elongate and of consistent concave shape along its length and positioned to have the concave shape wrapped partially around the pole but leaving a cooling gap between the inner concave side of the panel and the pole, the panel having a plurality of rearwardly extending spacer blocks located in a position the panel that is in the one case toward an upper end of the panel, and in another case, toward a lower end of the panel, and straps, each engaging the one or more of the spacer blocks and holding this or these against the pole and the panel to the pole thereby.

In preference, the blocks are electrically insulating material.

In further preference, the blocks each have a shape with a base portion attached to the panel and a further most portion of the panel being of smaller cross sectional area than the base portion.

In preference, each block is elongate and positioned so that its direction of elongation is parallel to a direction of elongation of the pole.

Further in preference, each block is of a triangular cross sectional shape and an apex of this triangular shape is a further most portion from the panel.

In preference, there are four blocks each aligned to have their direction parallel one to the other parallel to the direction and the elongation of the panel, one case, two of these being toward an upper end of the panel and in the other case the lower end of the panel.

In a further form the invention can reside in a plurality of low voltage electrical transmission poles commonly connected by wires effecting low voltage alternating current transmissions and to at least two of the poles next to each other there is provided the assembly as previously described herein.

For a better understanding of this invention it will now be described with the assistance of drawings in relation to an embodiment wherein

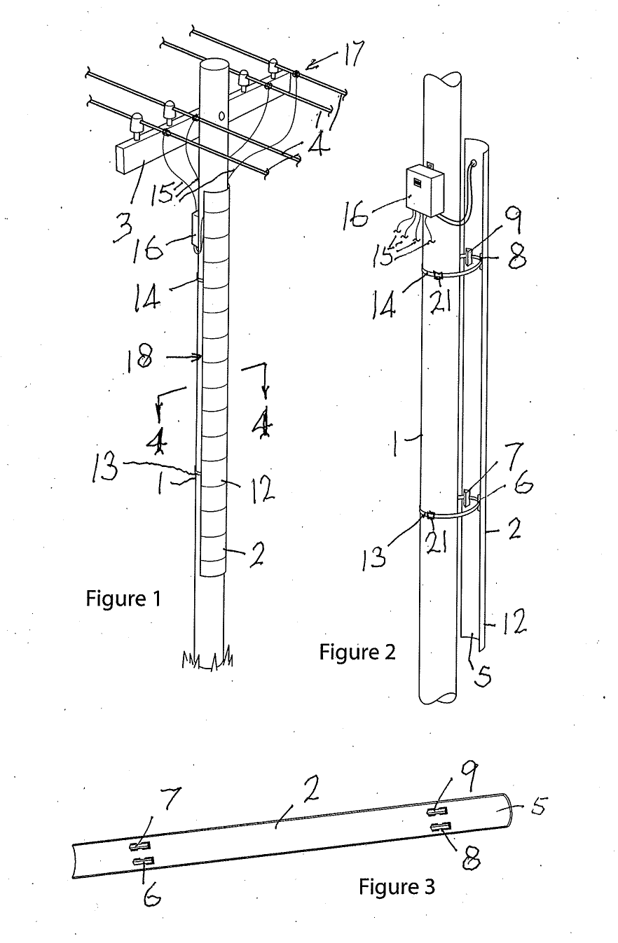

FIG. 1 is a perspective view of an assembly according to the embodiment,

FIG. 2 is a view from the side of the assembly as in FIG. 1 with the solar cell panel cross section,

FIG. 3 is a view of the solar panel with the attached blocks separately from being positioned on a telegraph pole,

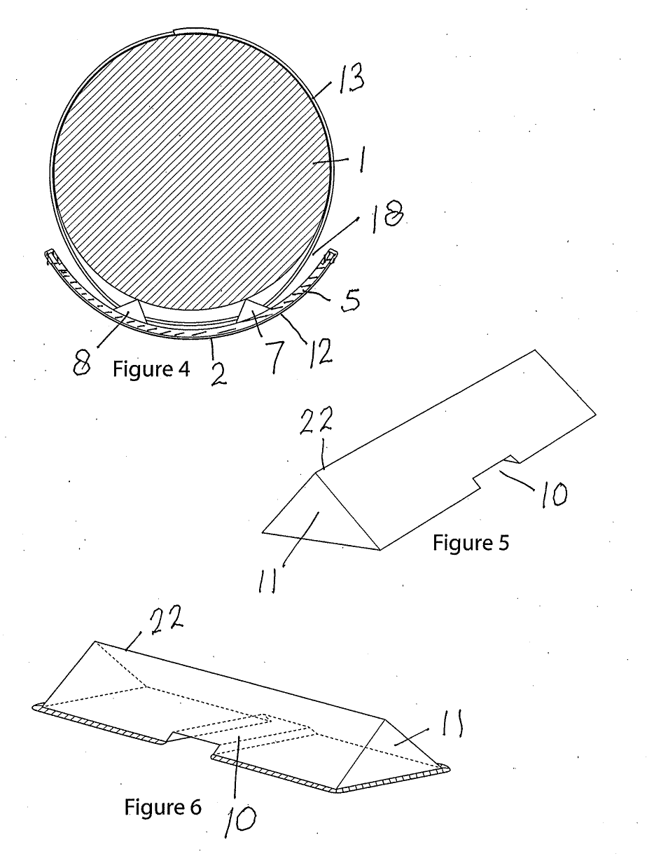

FIG. 4 is a cross-section along the lines 44 in FIG. 1,

FIG. 5 is a perspective view of a block separate from its attachment to the curved panel,

FIG. 6 is a perspective view of the block when attached to the panel going dotted outline the other aspects of the shape of the block.

Now referring to the drawings in details, the proposal is to have an economic facility providing distributed sources of electrical power which uses presently unused locations being specifically electrical transmission poles.

Such poles are ubiquitous and provide electrical transmission by supporting overhead electrical transmission wires at low voltage generally throughout the world.

Low voltage in the context of this invention is not specifically limited to being of conventional voltages but will include rephase transmissions providing 50 cycle or 15 voltage type electrical alternating power transmission or it can provide single phase transmissions at 240 volts or 50 hertz. Other conventional voltages include 110 volts usually provided at 60 hertz.

This is distinguished from medium voltages which will generally be above 1,000 volts though we are talking local distribution electrical power.

Such poles can be variously manufactured and used and include in many cases natural timber which in many cases are derived from the trunk of a tree and therefore have incidental changes in their shape circumference.

Alternate support systems can include metal tubular poles, metal and concrete poles often referred to as stobie poles, cement poles and further combination.

In this embodiment we are showing a conventional timber pole 1 to which is attached a curved elongate solar cell panel 2.

This is positioned beneath a cross tree 3 and supports in conventional manner electrical power lines 4.

The solar cells are held in this curved shape by being supported on a backing of pvc (although alternate options include polycarbonate) which in this case is a panel of generally constant thickness and is derived in this particular case by being a part of a conventionally manufactured plastic pipe.

The solar cell panel is of conventional manufacture but in this case it is a solar panel of amorphous silica being provided by United Solar Ovonic LLC in the United States specifically Uni-solar PVL-136 as an example.

The shape of the solar panel curved so as to be convex on its outside and concave on the inside is of a substantial length to take advantage of the available base on the power transmission pole 1.

The thin film solar bell panel (ppsnwo1) is held to its plastic backing by pinchweld shaped brackets which are held in a tight pinching relationship by stainless steel self tapping screws passing mutually through a backing material and the module material and adhesive is further used to attach the panel material to the backing.

The solar cell panel 2 being held in this structurally generally self supporting shape is nonetheless a backing support, attached to the pole 1 by firstly having four blocks at 6, 7 8 and 9 where each of the blocks is shaped as is shown specifically in FIGS. 5 and 6.

Accordingly, each of the blocks is of triangular cross sectional shape and this shape is maintained consistently throughout its length except there is a slot 9 across a base portion of the triangular shape 10 midway between the ends. Alternate shapes can include a semicircular shape along the length of the block.

Each of these blocks is secured by plastic welding to the plastic backing material 5.

The position of the blocks also ⅓ and ⅔^{rd} of the distance across from one side of the solar panel 2 to the other.

Each of the blocks is manufactured from a plastics material itself so as to provide an insulating.

Each of the blocks in this case 6 through 9 is aligned with the direction of elongation parallel to a direction of elongation of the solar cell panel 2 and this also aligns with the axis of the pole 1.

The position of each of the blocks is such that two of the blocks 6 and 7 are close to but not at one end of the solar panel 2 and the other two blocks are likewise toward but not at the other end of the solar panel 2.

In this way, each of the blocks when held against a pole provides a point support by having two widely spaced support points only along the length of the pole, means that the attachment can take account of irregularities in the shape and diameter of the pole 1 or any other form of pole and the stiffness or rigidity formed by the solar panel 2 allows these spaced apart location points to be effective in holding the panel 2 in place.

Each of the blocks 6 through 9 engages with its outer apex which in this case is a point alignment furthest from the face 12 of the panel 2 and then a strap 13 is mutually engaging the blocks and the pole holding these tight, the apex 11 of relatively sharp shape will be expected to imbed partially within the structure of the pole 1.

The straps including the upper one 13 and the lower one 14 are comprised of conventional strapping as used in many different occasions especially for packaging purposes and includes a conventional tie which holds the strap in place. Such technology is very well developed and is appropriate for this application. This can be of a plastics material or in a further embodiment is stainless steel.

Solar panel 2 is connected by electrical conduits 15 to an inverter and an apparatus for matching voltages 16 which is then connected in an appropriate way at typically 17 to the electrical transmission wires 4.

This arrangement provides a cooling gap 18 which by reason of the elongate shape and alignment of the blocks 6 through 9 will not be generally impeding convectional currents which provides both for relatively open access in this area but at least diminish providing a refuge for insects and other animals and is shaped to assist in capture of air currents when appropriate.

Further, by having the alignment of the face vertical this minimizes visual impact, and reduces significantly the vulnerability of the panel to collect dust and bird droppings. Further, any rain hitting the surface is more aggressively shed which assists in cleaning. Further, by having a curved shape there is less available top edge and room for birds to sit and further defecate.

In erecting the panel, it has been found that providing a first hanging point from a pole particularly where this is a wooden pole can assist by first supporting the panel from such a hanging point and then with some greater assurance, one can locate and tighten the straps for the long term securement. Any hanging point however is attached to the panel so that it will allow for horizontal movement of the panel with respect to the hanging point. In this embodiment the hanging point is provided by a coach bolt screwed into the pole initially and the panel is raised by a crane or other support to the appropriate height and then fitted with its aperture over the bolt. This bolt however is not tightened which allows for this horizontal freedom.

In a further form the invention can also reside in a method of achieving a supply of electrical power which includes the steps of attaching a solar cell panel of curved elongate shape with its curvature being consistent along its direction of elongation, on an electrical power transmission pole, holding such panel to the pole so that its curved shape wraps partially around the pole, by securing a strap through or behind one or more of blocks spacing the panel from the pole with a strap where the blocks are located only toward one end of the panel in one case and toward the other opposite end of the panel in the second case.

This method can further include the step of first positioning a hanging point with respect to the pole, hanging the panel so that it is suspended but not fixed in position horizontally with respect to the pole, then tying the panel to the pole with an upper strap in one case and a lower strap in the other which engages the respective blocks and holds the panel to the pole thereby.

1. A solar cell and alternating low voltage electrical transmission system assembly comprising
an electricity transmission pole,
a solar cell panel attached to a side of the pole,
the solar cell panel having a plurality of cells commonly electrically connected, an inverter effecting an electrical connection between the plurality of cells and the electrical transmission system, the panel being elongate and a consistent concave shape along its length,
and positioned to have the concave shape wrap partially around the pole but leaving a cooling gap between the inner concave side of the panel and the pole, the panel having a plurality of rearwardly extending spacer blocks located in a position of the panel that is in the one case toward an upper end of the panel and in another case toward a lower end of the panel, and straps, each engaging a one or more of the spacer blocks and holding this or these against the pole and the panel to the pole thereby.

2. The assembly as in claim 1, wherein each of the blocks are of electrically insulating material and have a shape with a base portion attached to the panel and a furthermost portion from the panel of smaller cross sectional area than the base portion.

3. The assembly as in claim 2, wherein each block is elongate and positioned so that its direction of elongation is parallel to a direction of elongation of the pole.

4. The assembly as in claim 3, wherein each block is of a triangular cross sectional shape and an apex of this triangular shape is a furthermost portion from the panel.

5. The assembly as in claim 3, wherein there are four blocks each aligned to have their direction of elongation parallel one to the other and parallel to the direction of elongation of the panel, in the one case of two of these being toward an upper end of the panel and in the other case of the remaining two being toward a lower end of the panel.

6. An arrangement where there are a plurality of transmission poles commonly connected by wires effecting low voltage alternating current transmissions and to at least two of the poles next to each other there is provided the assembly as in claim 1.

7. A method of achieving a supply of electrical power which comprises the steps of attaching a solar cell panel of curved elongate shape with its curvature being consistent along its direction of elongation, on an electrical power transmission pole, holding such panel to the pole so that its curved shape wraps partially around the pole, securing a strap through or behind one or more of blocks spacing the panel from the pole with a strap where the blocks are located only toward one end of the panel in one case and toward the other opposite end of the panel in the second case.

8. The method as in claim 7, further comprising the steps of first positioning a hanging point with respect to the pole, hanging the panel so that it is suspended but not fixed in position horizontally with respect to the pole, then tying the panel to the pole with an upper strap in one case and a lower strap in the other which engages the respective blocks and holds the panel to the pole thereby.
